(19) United States
(12) Patent Application Publication
(10) Pub. No.: US 2012/0163095 A1
(43) Pub. Date: Jun. 28, 2012

(54) SEMICONDUCTOR MEMORY DEVICE

(75) Inventor: Rieko TANAKA, Kanagawa-ken (JP)

(73) Assignee: Kabushiki Kaisha Toshiba, Minato-ku (JP)

(21) Appl. No.: 13/332,682

(22) Filed: Dec. 21, 2011

(30) Foreign Application Priority Data
Dec. 22, 2010 (JP) P2010-286761

(51) Int. Cl. G11C 16/10

(52) U.S. Cl. 365/185.22

(57) ABSTRACT

A semiconductor memory device includes a plurality of bit lines connected to memory cells; a sense amplifier connected to the plurality of bit lines; a memory unit configured to hold failure data of the bit lines; and a controller configured to perform control such that if it is judged that there is a failure in a second bit line adjacent to a first bit line selected in writing data on the basis of the failure data for the bit lines, the potential of the second bit line is set to a first potential in at least any one of programming and verification.

### CROSS-REFERENCE TO RELATED APPLICATIONS

This application is based upon and claims the benefit of priority of prior Japanese Patent Application No. 2010-286761, filed Dec. 22, 2010, the entire contents of which are incorporated herein by reference.

### FIELD

Embodiments described herein relate generally to a semiconductor memory device including a sense amplifier.

### BACKGROUND

NAND flash memories are known as an example of semiconductor memory devices. The writing method for NAND flash memories is a method (step-up method) where an initial program voltage (initial Vpgm) is firstly applied to a selected word line and then the initial program voltage is incremented by a step-up voltage (ΔVpgm) to apply a program voltage to the word line.

According to this writing method, each memory cell holds a state having a high threshold voltage as a written state (“0” data), and holds a state having a low threshold voltage as an erased state (“1” data).

### BRIEF DESCRIPTION OF THE DRAWINGS

FIG. 1 is a block diagram illustrating the overall configuration of a NAND flash memory, which is a semiconductor memory device of a first embodiment.

FIG. 2 is a block diagram illustrating the structure of a memory-cell array of the first embodiment.

FIG. 3 is a circuit diagram illustrating the configuration of a selector circuit of the first embodiment.

FIG. 4 is a circuit diagram illustrating the configuration of a switching circuit of the first embodiment.

FIG. 5 is a timing chart illustrating the write operation of the semiconductor device of the first embodiment.

FIG. 6 is a timing chart illustrating the write operation of the semiconductor memory device of a comparative example.

FIG. 7 is a circuit diagram illustrating the configuration of a switching circuit of a second modification.

FIG. 8 is a circuit diagram illustrating the configuration of a switching circuit of a third modification.

FIG. 9 is a block diagram illustrating a NAND flash memory and a flash controller of this embodiment.

### DETAILED DESCRIPTION

Some embodiments of the invention are described below by referring to the drawings. In the following description, the same portions are denoted by the same reference numerals throughout the drawings. In addition, proportions of dimensions in the drawings are not restricted to those shown in the drawings.

In general, according to one embodiment of the invention, a semiconductor memory device includes a plurality of bit lines connected to memory cells; a sense amplifier connected to the plurality of bit lines; a memory unit configured to hold failure data of the bit lines; and a controller configured to perform control such that if it is judged that there is a failure in a second bit line adjacent to a first bit line selected in writing data on the basis of the failure data for the bit lines, the potential of the second bit line is set to a first potential in at least any one of programming and verification.

### First Embodiment

If there is a failure in a bit line that is adjacent to a selected bit line (e.g., if the adjacent bit line is in a high-resistant state), a semiconductor memory device of this first embodiment does not change the voltage of the adjacent bit line in the programming and verification performed in a data-write operation. Thereby, the erroneous reading can be prevented in the verification of a memory cell connected to the selected bit line.

### [Configuration of Semiconductor Memory Device]

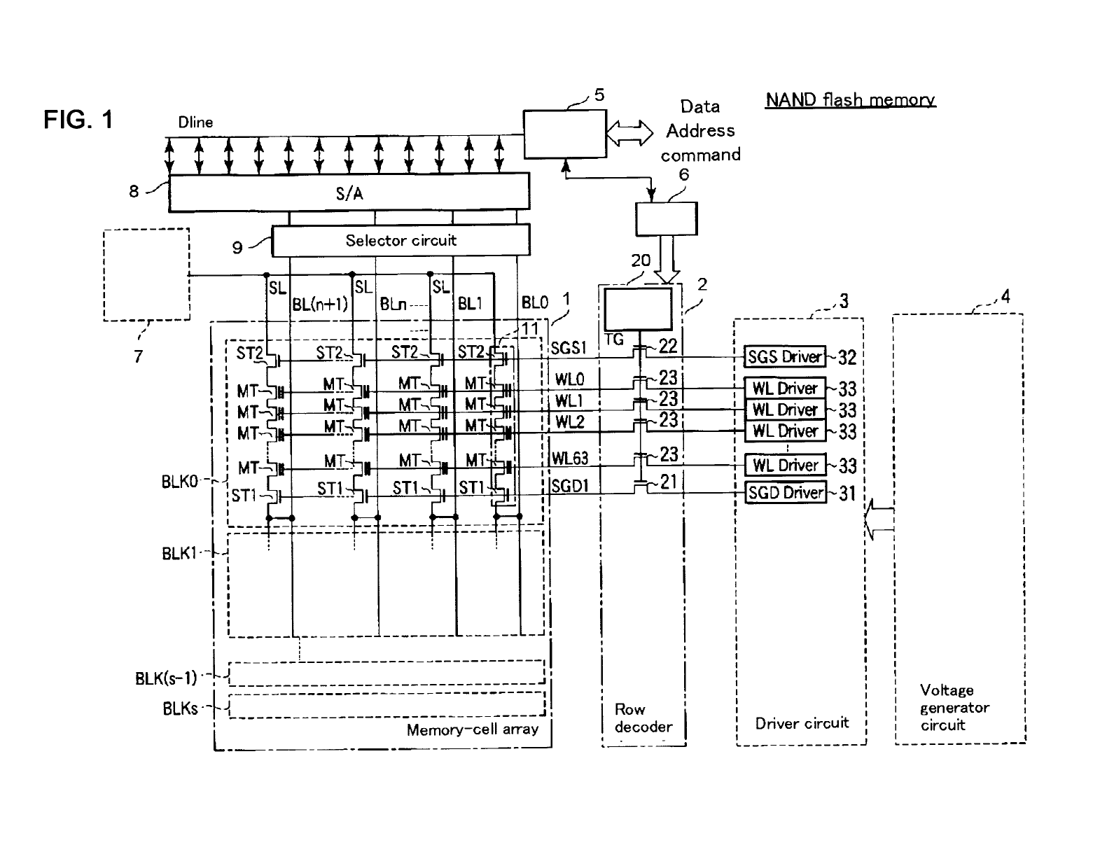

The semiconductor memory device of this first embodiment is described by taking up a NAND flash memory shown in FIG. 1 as an example. As FIG. 1 shows, the NAND flash memory includes a memory-cell array 1, a row decoder 2, a driver circuit 3, a voltage generator circuit 4, a data input-and-output circuit 5, a controller 6, a source-line (SL) driver 7, a sense amplifier 8, and a selector circuit 9.

### <Memory-Cell Array>

The memory-cell array 1 includes blocks BLK0 to BLKs (s is a natural number) each including plural non-volatile memory cells MT. In addition, each of the blocks BLK0 to BLKs includes plural NAND strings 11 each including plural non-volatile memory cells MT, and selector transistors ST1 and ST2. Generally, 64 memory cells MT are provided between the selector transistors ST1 and ST2 so that the current paths of the 64 memory cells can be connected in series to one another. Of these memory cells MT that are connected in series to one another, the memory cell MT on a first end has a drain region that is connected to the source region of the selector transistor ST1, while the memory cell MT on a second end has a source region that is connected to the drain region of the selector transistor ST2. In addition, every two adjacent memory cells MT share a source and a drain.

Note that the number of the memory cells MT that are connected in series to one another is not limited to 64. The number may be 128, 256, 512 or the like, and the number is not limited.

Each memory cell MT is capable of storing data with two or more values. Each memory cell MT has a structure known as the FG structure, which includes a floating gate (conductive layer) and a control gate. The floating gate is formed on a gate insulator film that is formed on a p type semiconductor substrate. The control gate is formed on an inter-gate insulator film that is formed on the floating gate. Note that the structure of each memory cell MT is not limited to the above-described FG structure, and may be a MONOS structure which includes a charge accumulator layer (e.g., an insulator film), an insulator film (an insulator film with a dielectric constant higher than that of the charge accumulator layer), and a control gate. The charge accumulator layer is formed on a gate insulator film that is formed on a semiconductor substrate. The insulator film is formed on the charge accumulator layer. The control gate is formed on the insulator film.

The control gate of each memory cell MT is electrically connected to a word line WL. The drain of each memory cell MT is electrically connected to a bit line BL. The source of each memory cell MT is electrically connected to a source line.

The control gates of all the memory cells MT that are located in a single row are connected to a respective one of word lines WL0 to WL63. The gate electrodes of all the selector transistors ST1 for the memory cells MT that are located on a single row are connected to a select gate line SGD1 while the gate electrodes of all the selector transistors ST2 for the memory cells MT that are located on a single row are connected to a select gate line SGS1.

In the memory-cell array 1, the drains of all the selector transistors ST1 that are located in a single column are connected to a respective one of bit lines BL0 to BLn. The sources of all the selector transistors ST2 are connected to a single source line SL.

In addition, all the plural memory cells MT that are connected to a single word line WL are grouped together to be a unit called a “page.” Data is collectively written in all the memory cells MT in a single page. In addition, data is collectively erased from all the plural memory cells MT that belong to a single block BLK.

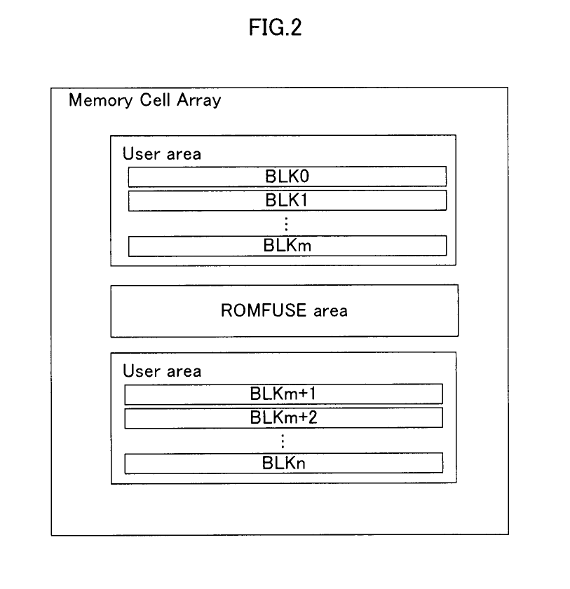

As FIG. 2 shows, the memory-cell array 1 includes, for example, plural user areas and a ROMFUSE area. The user areas are used to hold ordinary data. The ROMFUSE area are used to hold a BADCOL signal, which is a signal indicating a bad column. More details about the BADCOL signal will be described later. In addition, the ROMFUSE area holds management data for the NAND flash memory.

### <Row Decoder>

The row decoder 2 includes a block decoder 20, and transfer transistors (N channel MOS transistors) 21 to 23. When data is written, read, or erased, the block decoder 20 decodes a block address provided by the controller 6, and selects a block BLK on the basis of the decode result. The block decoder 20 sends a block-selection signal to the transfer transistors 21 to 23. Thus, the transfer transistors 21 to 23 are turned ON. Then, on the basis of the selection signal provided by the block decoder 20, the row decoder 2 transfers the voltages given by the driver circuit 3 to the select gate lines SGD1 and SGS1, and also to the word lines WL0 to WL63.

### <Driver Circuit>

The driver circuit 3 includes select gate line drivers 31 and 32, and also includes word line drivers 33. A select gate line driver 31 is provided for each single select gate line SGD 1 while a select gate line driver 32 is provided for each single select gate line SGS1. A word line driver 33 is provided for each single word line WL. In this embodiment, a set of word line drivers 33 and select gate line drivers 31 and 32 is provided for each of the blocks BLK0 to BLKs.

When data is written, read, erased, or verified, the select gate line drivers 31 transfers, for example, a signal sgd to the gates of the selector transistors ST1 via the select gate line SGD1.

When data is written, read, erased, or verified, the select gate line driver 32, like the select gate line driver 31, transfers a necessary voltage to the gates of the selector transistors ST2 via the select gate line SGS1 corresponding to the selected block BLK. Specifically, the select gate line driver 32 transfers a signal sgs to the gates of the selector transistors ST2.

### <Voltage Generator Circuit>

The voltage generator circuit 4 generates voltages that are necessary for the programming, the reading, and the erasing of the data by either increasing or decreasing a voltage provided from outside. The voltage generator circuit 4 supplies the voltages thus generated to the driver circuit 3.

### <Data Input-and-Output Circuit>

The data input-and-output circuit 5 outputs, to the controller 6, addresses and commands that are supplied from a host via an unillustrated I/O terminal. In addition, the data input-and-output circuit 5 outputs write data to the sense amplifier 8 via data line Dline.

In addition, when data is outputted to a host, the sense amplifier 8 outputs the amplified data on the basis of the control by the controller 6. Then, the data input-and-output circuit 5 receives the amplified data via the data line Dline, and then outputs the received data to the host via the I/O terminal.

### <Controller>

The controller 6 controls the overall operations of the NAND flash memory. Specifically, on the basis of the addresses and commands provided by an unillustrated host via the data input-and-output circuit 5, the controller 6 executes operational sequences for the writing, the reading, or the erasing of data. The controller 6 generates a block-selection signal and a column-selection signal on the basis of the address and the operational sequence.

The controller 6 outputs the above-mentioned block-selection signal to the row decoder 2. In addition, the controller 6 outputs the column-selection signal to the sense amplifier 11. The column-selection signal is a signal used for the selection, in the column directions, of the sense amplifier 11.

The controller 6 receives a control signal supplied by an unillustrated memory controller. On the basis of the control signal thus supplied, the controller 6 judges whether the signal supplied to the data input-and-output circuit 5 from the host via the unillustrated I/O terminal is an address or data.

### <Source-Line (SL) Driver>

The source-line (SL) driver 7 is put into action by an internal control signal inputted by the controller 6. For example, in the erasing, the source-line (SL) driver 7, controlled by the controller 6, transfers a voltage VDD from the side of the source line SL to the side of the bit line BL.

### <Sense Amplifier>

In the read operation, the sense amplifier 8 sense-amplifies and then holds temporarily the data read from the memory-cell array 1. Then, the sense amplifier 8 transfers the data thus held to the data input-and-output circuit 5 via the data line Dline. In the write operation, the sense amplifier 8 transfers, to the memory-cell array 1 via the bit line BL, the data that has been transferred from the data input-and-output circuit 5.

### <Selector Circuit>

The selector circuit 9 connects either the selected even-numbered bit lines BL (BL0, BL2, . . . ) or the selected odd-numbered bit lines BL (BL1, BL3, . . . ) to the sense amplifier 8. Specifically, if the even-numbered bit lines BL are selected, the selector circuit 9 connects the even-numbered bit lines BL to the sense amplifier 8. In the meanwhile, the selector circuit 9 leaves the odd-numbered bit lines BL unconnected to the sense amplifier 8.

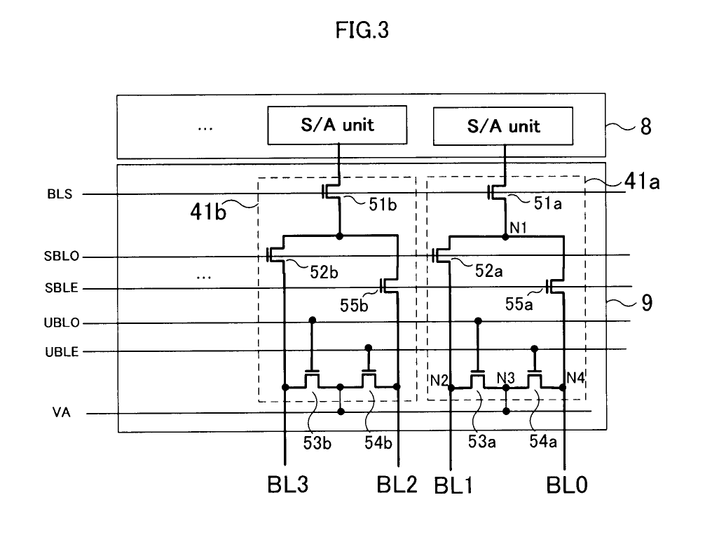

Next, the configuration of the selector circuit 9 of this first embodiment is described by referring to the circuit diagram shown in FIG. 3.

The selector circuit 9 includes plural selector units 41 (41a, 41b, . . . ). Each of the selector units 41 is connected to two adjacent bit lines BL. Specifically, as FIG. 3 shows, each selector unit 41 is connected to one of the even-numbered bit lines BL and one of the odd-numbered bit lines BL. If each of the plural selector units 41 selects, for example, the corresponding even-numbered bit line BL, the even-numbered bit lines BL of the memory-cell array 1 are connected to the sense amplifier 8. Each component of the selector circuit 9 is described below by taking the selector unit 41a shown in FIG. 3 as an example.

The selector unit 41a includes five N channel MOS transistors 51a to 55a. A first end of the power-supply route of the transistor 51a is connected to the sense amplifier 8. A second end of the power-supply route of the transistor 51a is connected to a node N1 (a node to which a first end of the power-supply route of the transistor 52a and a first end of the power-supply route of the transistor 55a are connected). The gate of the transistor 51a receives the input of a BLS signal. The BLS signal mentioned above is a signal to control the electrical connection between the sense amplifier 8 and the bit lines BL. The BLS signal is at the “H” level in the read operation and the write operation, while the BLS signal is at the “L” level in the erase operation. Thus, the transistor 51a is cut off in the erase operation.

A second end of the power-supply route of the transistor 52a is connected to the bit line BL1 and a first end of the power-supply route of the transistor 53a. Stated differently, the second end of the power-supply route of the transistor 52a is connected to a node N2 as shown in FIG. 3. The gate of the transistor 52a receives the input of an SBLO signal. The SBLO signal is a control signal that is at the “H” level to turn the transistor 52a ON if the bit line BL1 is selected. If, conversely, the bit line BL0 is selected, the SBLO signal is at the “L” level to turn the transistor 52a OFF.

As FIG. 3 shows, a second end of the power-supply route of the transistor 53a is connected to a node N3 (a node to which a first end of the power-supply route of the transistor 54a is also connected). The gate of the transistor 53a receives the input of a UBLO signal. A predetermined voltage VA (details of which will be described later) is inputted to the node N3. The UBLO signal is a control signal that is at the “L” level to turn the transistor 53a OFF if the odd-numbered bit line BL1 is selected. If, conversely, the even-numbered bit line BL0 is selected, the UBLO signal is at the “L” level to turn the transistor 53a ON and thus to transfer the voltage VA to the bit line BL1.

A second end of the power-supply route of the transistor 54a is connected to the bit line BL0 and a second end of the power-supply route of the transistor 55a. Stated differently, the second end of the power-supply route of the transistor 54a is connected to a node N4 as shown in FIG. 3. The gate of the transistor 54a receives the input of a UBLE signal. The UBLE signal is a control signal that is at the “L” level to turn the transistor 54a OFF if the even-numbered bit line BL0 is selected. If, conversely, the odd-numbered bit line BL1 is selected, the UBLE signal is at the “H” level to turn the transistor 54a ON and thus to transfer the voltage VA to the bit line BL0.

The gate of the transistor 55a receives the input of an SBLE signal. The SBLE signal is a control signal that is at the “H” level to turn the transistor 55a ON if the even-numbered bit line BL0 is selected. If, conversely, the odd-numbered bit line BL1 is selected, the SBLE signal is at the “L” level to turn the transistor 55a OFF.

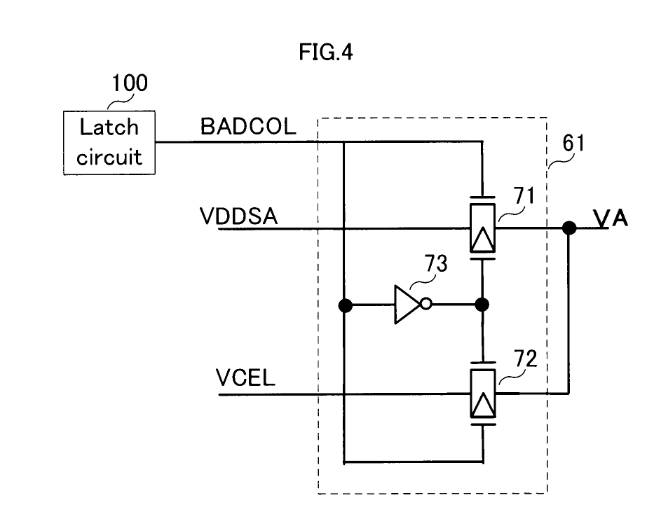

The voltage VA mentioned above is controlled by a switching circuit that receives the input of a voltage VDDSA and that of a voltage VCEL. The switching circuit is described referring to FIG. 4.

As FIG. 4 shows, a switching circuit 61 includes two transfer gates 71 and 72, and also includes an inverter 73.

A first end of the power-supply route of the transfer gate 71 receives the input of the voltage VDDSA. A second end of the power-supply route of the transfer gate 71 is connected to the node N3 shown in FIG. 3. In addition, the gate of an N channel MOS transistor that is included in the transfer gate 71 receives the input of the BADCOL signal. The gate of a P channel MOS transistor included in the transfer gate 71 receives, via the inverter 73, the input of a /BADCOL signal (an inversion signal of the BADCOL signal). The voltage VDDSA mentioned here is a potential to be applied to the non-selected bit lines in the programming.

A first end of the power-supply route of the transfer gate 72 receives the input of the voltage VCEL. A second end of the power-supply route of the transfer gate 72 is connected to the node N3 shown in FIG. 3. In addition, the gate of an N channel MOS transistor that is included in the transfer gate 72 receives, via the inverter 73, the input of the /BADCOL signal. The gate of a P channel MOS transistor included in the transfer gate 71 receives the input of the BADCOL signal. The voltage VCEL mentioned here is a potential to be applied to the non-selected bit lines in the programming and a ground potential in the verification.

A latch circuit 100 is connected to the gate of the N channel MOS transistor included in the transfer gate 71, to the gate of the P channel MOS transistor included in the transfer gate 72, and the input terminal of the inverter 73. The same number of the latch circuits 100 as the number of the selector units 41 is provided. The latch circuit 100 has a function, for example, of holding the BADCOL signal held in the ROMFUSE area when the semiconductor device is powered ON.

The BADCOL signal is a signal that is at the “H” level if there is a failure in the bit lines BL, and that is at the “L” level if there is no failure in the bit lines BL. Whether there is a failure in the bit lines BL or not is judged, for example, when a die sort test is performed. If it is judged, at the test, that there is a failure, the failure data is held, for example, in the ROMFUSE area (memory unit) of the memory-cell array 1.

[Write operation in Semiconductor Device]

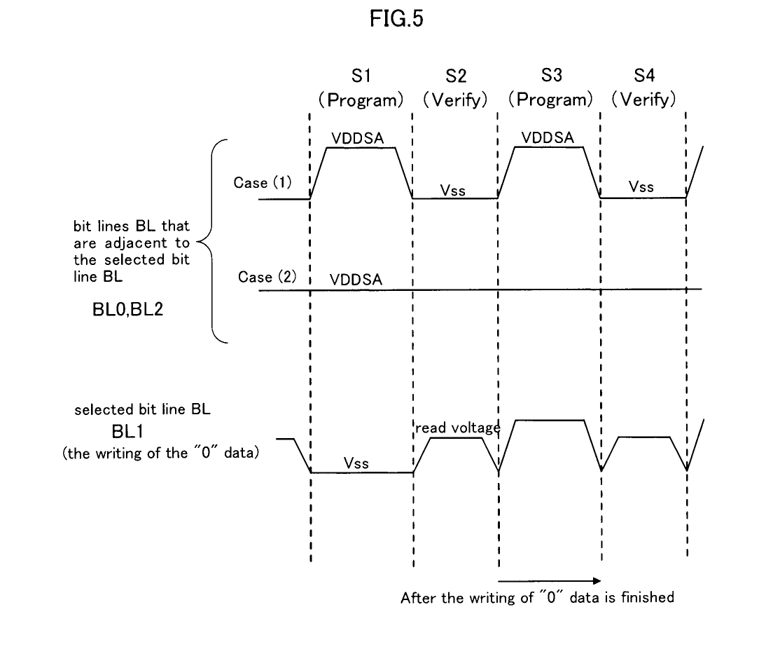

Next, the write operation performed by the semiconductor memory device of this first embodiment is described by referring to the timing charts shown in FIG. 2, FIG. 4 and FIG. 5. For the sake of descriptive convenience, the BADCOL signal of the ROMFUSE area is assumed to be held in the latch circuit 100 when the semiconductor memory device is powered ON. The following two cases that are differentiated by the data held in the latch circuit 100 are described below: a case (1) where there is no failure in any of the bit lines BL that are adjacent to the selected bit line BL; and a case (2) where there is a failure in a bit line BL that is adjacent to the selected bit line BL.

Firstly, the case (1) where there is no failure in any of the bit lines BL0 and BL2 that are adjacent to the selected bit line BL1 is described by referring to FIG. 5.

As FIG. 5 shows, when the programming is performed at step S1, the bit line BL1 is at the ground potential Vss corresponding to the writing of the “0” data, and the voltage VDDSA is applied to the bit lines BL0 and BL2.

Thus, the BLS signal becomes the “H” level, the SBLO signal becomes the “H” level, the SBLE signal becomes the “L” level, the UBLO signal becomes the “L” level, and the UBLE signal becomes the “H” level. Hence, the transistors 51a, 52a, and 54a in the selector unit 41a are turned ON while the transistors 53a and 55a are turned OFF. Accordingly, the bit line BL1 is connected to the sense amplifier 8. Consequently, the ground potential Vss for the writing of “0” data is applied to the bit line BL1. In the meanwhile, the bit lines BL0 and BL2 are connected to the node N3. So the predetermined voltage VA is applied to the bit lines BL0 and BL2.

Now that there is no failure in any of the bit lines BL0 and BL2, the BADCOL signal becomes the “L” level. Thus the transfer gate 71 is cut off, while the transfer gate 72 is turned ON. Consequently, the voltage VCEL (in the programming, the voltage VCEL=the voltage VDDSA) is transferred to the bit lines BL0 and BL2.

When the verification is performed at step S2, a read voltage is applied to the bit line BL1, and the bit lines BL0 and BL2 are kept at the ground potential Vss (in the verification, the voltage VCEL=the ground potential Vss). The read voltage is transferred from the sense amplifier 8.

The above-described steps S1 and S2 are preformed repeatedly until the threshold voltages of all the memory cells exceed a predetermined verification voltage.

When the writing of “0” data is finished, the voltage VDDSA is applied to the bit line BL1 as shown at step S3.

Next, the case (2) where there is a failure in the bit line BL2 that is adjacent to the selected bit line BL1 is described.

As FIG. 5 shows, when the programming is performed at step S1, the bit line BL1 is at the ground potential Vss corresponding to the writing of the “0” data, and the voltage VDDSA is applied to the bit lines BL0 and BL2.

Thus, the BLS signal becomes the “H” level, the SBLO signal becomes the “H” level, the SBLE signal becomes the “L” level, the UBLO signal becomes the “L” level, and the UBLE signal becomes the “H” level. Hence, the transistors 51a, 52a, and 54a in the selector unit 41a are turned ON while the transistors 53a and 55a are turned OFF. Accordingly, the bit line BL1 is connected to the sense amplifier 8. Consequently, the ground potential Vss for the writing of “0” data is applied to the bit line BL1. In the meanwhile, the bit lines BL0 and BL2 are connected to the node N3. So the predetermined voltage VA is applied to the bit lines BL0 and BL2.

Now that there is a failure in the bit lines BL0 and BL2, the BADCOL signal becomes the “H” level. Thus the transfer gate 71 is turned ON, while the transfer gate 72 is turned OFF. Consequently, the voltage VDDSA is transferred to the bit lines BL0 and BL2.

When the verification is performed at step S2, a read voltage is applied to the bit line BL1, and the voltage VDDSA is transferred to the bit lines BL0 and BL2. The read voltage is transferred from the sense amplifier 8.

Consequently, the voltage VDDSA is transferred to the bit lines BL0 and BL2 in the programming and verification.

### Effects of First Embodiment

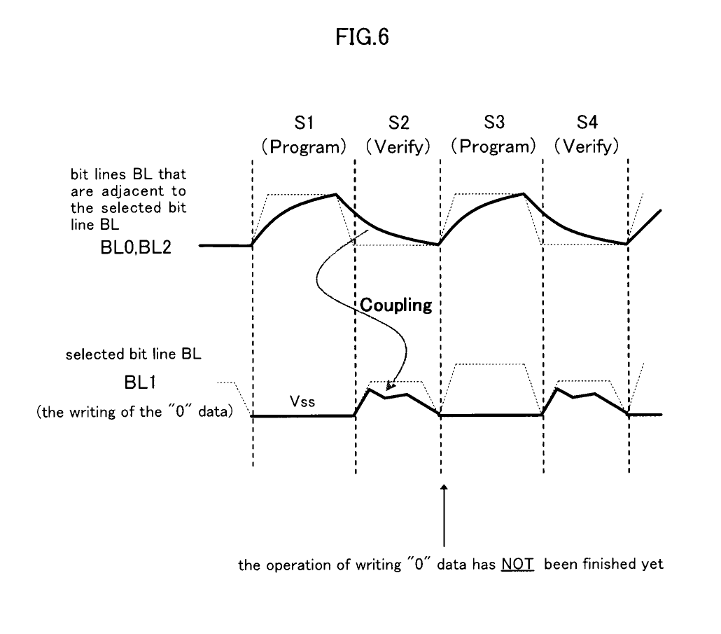

With the configuration and the operation described above, the semiconductor memory device of this first embodiment can improve the reliability without increasing the area of a column redundancy circuit. The effects are described in detail below referring to FIG. 6.

In the semiconductor memory device of this first embodiment, in the programming and verification, the voltage VDDSA is transferred to the bit line BL where a failure occurs. Hence, in the programming and verification, the voltage of the bit line BL where a failure occurs is not changed at all. Thus, the selected bit line BL can reduce the negative influence of the coupling of the adjacent bit lines BL in the write operation.

Accordingly, in the verification, it is possible to prevent such an inconvenience that the coupling of the adjacent bit lines BL impedes the rising of the voltage to be applied to the selected bit line BL up to the predetermined read voltage.

As FIG. 6 shows, if there is a failure of high resistance in any of the adjacent bit lines BL, it takes a longer time for the potential of the adjacent bit lines BL to drop down to the ground potential Vss in the verification (at step S2). Hence, also in a case where “0” data has already been written in the memory cells that are connected to the selected bit lines BL, the coupling of the adjacent bit lines BL sometimes impedes the rising of the voltage to be applied to the selected bit line BL up to the predetermined read voltage. Consequently, it is judged that the operation of writing “0” data in the memory cells has not been finished yet, and thus the steps S1 and S2 are to be repeated further. Accordingly, over-programming and erroneous writing occur in the memory cells.

In the semiconductor memory device of this first embodiment, however, the voltage of the selected bit line BL isn't affected by the coupling of the adjacent bit lines BL because voltages of the adjacent bit lines BL do not change in the verification. Therefore the predetermined read voltage is applied to the selected bit line BL in the verification, so that the erroneous writing in the memory cells can be avoided. As a consequence, the reliability of the memory cells can be improved.

Incidentally, it is conceivable that the bit lines BL that are adjacent to the selected bit line BL belong to different columns and the adjacent bit lines BL, if a failure occurs in these adjacent bit lines BL, are replaced for the columns that are adjacent to the selected bit line BL with redundancies. The semiconductor memory device of this embodiment, however, can improve the reliability of the memory cells without the use of such redundancies.

As has been described above, the semiconductor memory device of this embodiment can improve the reliability without increasing the area of the column redundancy circuit.

### (First Modification)

In the semiconductor memory device of the first embodiment described above, in the programming and verification, the voltage VDDSA is transferred to the bit line BL where a failure occurs. In this first modification, in programming and verification, the voltage VSS is transferred to the bit line BL where a failure occurs.

Not only in the first embodiment but also in this first modification, the voltage of the bit line BL where a failure occurs does not change at all in the programming or verification. Accordingly, the selected bit line BL can reduce the negative influence of the coupling of the adjacent bit lines BL in the write operation. Consequently, it is possible to improve the reliability without increasing the area of the column redundancy circuit.

In addition, in the semiconductor memory device of this first modification, the voltage VSS is transferred in the programming and verification. Accordingly, the power consumption in the write operation can be further reduced, as compared with the case of the semiconductor memory device of the first embodiment.

### (Second Modification)

In the semiconductor memory device of the first embodiment, the voltage VDDSA is transferred to the bit line BL where a failure occurs in the programming and verification. In this second modification, however, the voltage VDDSA is transferred in the programming but the bit line BL where a failure occurs is floating in the verification.

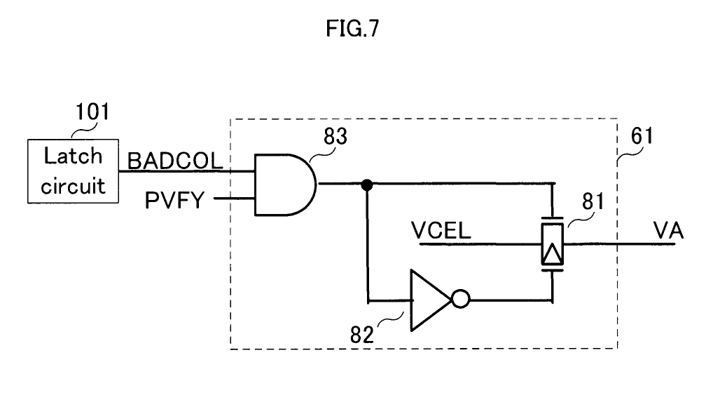

Specifically, as FIG. 7 shows, a switching circuit 61 of this second modification includes a transfer gate 81, an inverter 82, and an AND gate 83. A first end of the current path of the transfer gate 81 receives the input of a voltage VCEL. A second end of the current path of the transfer gate 81 is connected to a node N3. The gate of an N channel MOS transistor included in the transfer gate 81 receives the input from the output of the AND gate 83. The gate of a P channel MOS transistor receives the input from the output of the AND gate 83 via the inverter 82.

The AND gate 83 receives the input of a BADCOL signal and the input of a PVFY signal. The PVFY signal is a signal that is at the “L” level at the time of programming and is at the “H” level in the verification.

A latch circuit 101 is connected to one of the input terminals of the AND gate 83. The same number of the latch circuits 101 are provided as the number of selector units 41. Each latch circuit 101 has a function, for example, of holding a BADCOL signal that is held in the ROMFUSE area when the semiconductor memory device is powered ON.

In this way, the adjacent bit lines BL can be floating in the verification.

Not only in the first embodiment but also in this second modification, the voltage of the bit line BL where a failure occurs does not change at all in the programming or verification. Accordingly, the selected bit line BL can reduce the negative influence of the coupling of the adjacent bit lines BL in the write operation. Consequently, it is possible to improve the reliability without increasing the area of the column redundancy circuit.

Incidentally, suppose a case of a comparative example where if there is a failure in any of the adjacent bit lines BL, erroneous writing occurs in the memory cells that are connected to the bit line BL and the threshold distribution of the memory cells is raised up. In this case, the memory cells connected to the selected bit line BL sometimes have data failure caused by the adjacent effect of the memory cells connected to the adjacent bit lines BL.

In the semiconductor memory device of this second modification, however, the voltage VDDSA is transferred in the programming. Hence, even if there is a failure in any of the adjacent bit lines BL, erroneous writing in the memory cells connected to the bit line BL can be reduced. As a consequence, data failure of the selected memory cells can be reduced, and the reliability can be improved.

### (Third Modification)

In the semiconductor memory device of the first embodiment, the voltage VDDSA is transferred to the bit line BL where a failure occurs in the programming and verification. In this third modification, however, the bit line BL where a failure occurs is floating in the programming and verification.

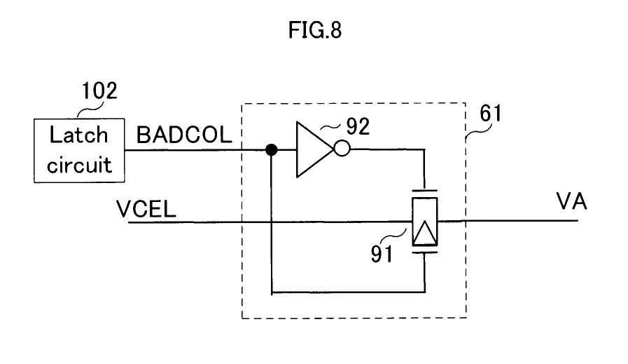

Specifically, as FIG. 8 shows, a switching circuit 61 of this third modification includes a transfer gate 91 and an inverter 92. A latch circuit 102 is connected to the input terminal of the inverter 92 and to the gate of a P channel MOS transistor included in the transfer gate 91. The same number of the latch circuits 102 are provided as the number of selector units 41. Each latch circuit 102 has a function, for example, of holding a BADCOL signal that is held in the ROMFUSE area when the semiconductor memory device is powered ON. If the BADCOL signal is at the “H” level, the transfer gate 91 is cut off. Hence, the bit line where a failure occurs is floating.

Not only in the first embodiment but also in this third modification, the voltage of the bit line BL where a failure occurs does not change at all in the programming or verification. Hence, the selected bit line BL can reduce the negative influence of the coupling of the adjacent bit lines BL in the write operation. Consequently, it is possible to improve the reliability without increasing the area of the column redundancy circuit.

In addition, in the semiconductor memory device of this third modification, the bit lines BL are floating in the programming and verification. Hence, the power consumption in the write operation can be reduced, as compared with the cases of the first embodiment, the first modification, and the second modification.

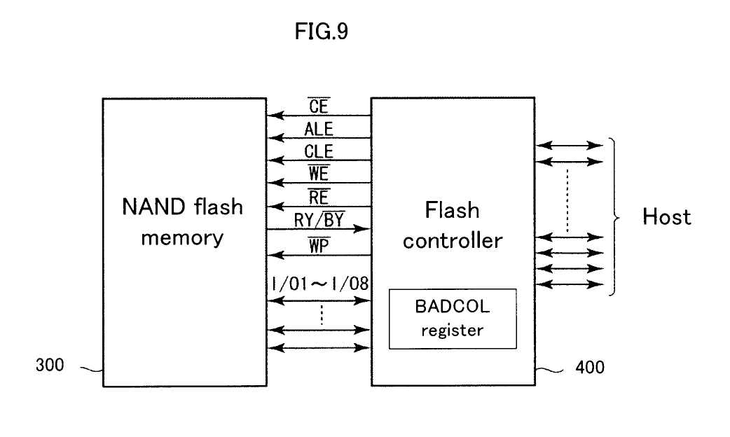

In this embodiment, a NAND flash memory includes latch circuits 100, 101, and 102. As FIG. 9 shows, a flash controller 400 may hold a BADCOL register corresponding to the latch circuits. Thus, when the semiconductor memory device is powered ON, a BADCOL signal is read from the ROMFUSE area of the NAND flash memory 300 to the BADCOL register. Alternatively, the flash controller 400 may be controlled so as to input a BADCOL signal into the switching circuit 61.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of bit lines connected to memory cells;
a sense amplifier connected to the plurality of bit lines;
a memory unit configured to hold failure data of the bit lines; and
a controller configured to perform control such that if it is judged that there is a failure in a second bit line adjacent to a first bit line selected in writing data on the basis of the failure data for the bit lines, the potential of the second bit line is set to a first potential in at least any one of programming and verification.

2. The semiconductor memory device of claim 1, wherein the first potential is a potential to be applied to a non-selected bit line.

3. The semiconductor memory device of claim 2, wherein the controller performs control such that the potential of the second bit line is floating in verification.

4. The semiconductor memory device of claim 1, further comprising:
a bit-line selector unit connected between the plurality of bit lines and the sense amplifier; and
a data line configured to transfer a potential to the second bit line, wherein
the bit-line selector unit includes:
a first selector transistor configured to connect the first bit line and the sense amplifier to each other;
a second selector transistor configured to disconnect the first bit line and the data line from each other;
a third selector transistor configured to connect the second bit line and the data line to each other; and
a fourth selector transistor configured to disconnect the second bit line and the sense amplifier from each other.

5. The semiconductor memory device of claim 2, further comprising:
a bit-line selector unit connected between the plurality of bit lines and the sense amplifier; and
a data line configured to transfer a potential to the second bit line, wherein
the bit-line selector unit includes:
a first selector transistor configured to connect the first bit line and the sense amplifier to each other;
a second selector transistor configured to disconnect the first bit line and the data line from each other;
a third selector transistor configured to connect the second bit line and the data line to each other; and
a fourth selector transistor configured to disconnect the second bit line and the sense amplifier from each other.

6. The semiconductor memory device of claim 3, further comprising:
a bit-line selector unit connected between the plurality of bit lines and the sense amplifier; and
a data line configured to transfer a potential to the second bit line, wherein
the bit-line selector unit includes:
a first selector transistor configured to connect the first bit line and the sense amplifier to each other;
a second selector transistor configured to disconnect the first bit line and the data line from each other;
a third selector transistor configured to connect the second bit line and the data line to each other; and
a fourth selector transistor configured to disconnect the second bit line and the sense amplifier from each other.

7. The semiconductor memory device of claim 4 further comprising a switching circuit connected to the data line, wherein
the first potential and a second potential that is to be applied to a non-selected bit line are inputted to the switching circuit, and
the switching circuit outputs the first potential if there is a failure in the second bit line.

8. The semiconductor memory device of claim 7, wherein the switching circuit includes:
a first transfer gate that has a current path with a first end connected to the data line and with a second end receiving an input of the first potential;
a second transfer gate that has a current path with a first end connected to the data line and with a second end receiving an input of the second potential; and
an inverter connected to agate of the first transfer gate and a gate of the second transfer gate.

9. The semiconductor memory device of claim 8, wherein a signal indicating whether or not there is a failure in the second bit line is inputted to the inverter, the gate of the first transfer gate, and the gate of the second transfer gate.

10. The semiconductor memory device of claim 9, wherein in programming or verification, the controller acquires, from the memory unit, a signal indicating whether or not there is a failure in the second bit line.

11. The semiconductor memory device of claim 4 further comprising a switching circuit connected to the data line, wherein
a second potential to be applied to a non-selected bit line is inputted to the switching circuit, and
the switching circuit makes the data line floating when there is a failure in the second bit line.

12. The semiconductor memory device of claim 11, wherein the switching circuit includes:
a transfer gate that has a current path with a first end connected to the data line and with a second end receiving an input of the second potential;
an inverter connected to a gate of the transfer gate; and
an AND gate that has an output terminal connected to the gate of the transfer gate and an input terminal of the inverter.

13. The semiconductor memory device of claim 11, wherein a signal indicating whether or not there is a failure in the second bit line is inputted to the AND gate.

14. The semiconductor memory device of claim 11, wherein
the switching circuit includes:
a transfer gate that has a current path with a first end connected to the data line and with a second end receiving an input of the second potential; and
an inverter connected to a gate of the transfer gate, and
a signal indicating whether or not there is a failure in the second bit line is inputted to an input terminal of the inverter.

15. A semiconductor memory device comprising:
a plurality of bit lines connected to memory cells;
a sense amplifier connected to the plurality of bit lines;
first means for holding failure data of the bit lines; and
second means for performing control such that if it is judged that there is a failure in a second bit line adjacent to a first bit line selected in writing data on the basis of the failure data for the bit lines, the potential of the second bit line is set to a first potential in at least any one of programming and verification.
